(19) United States
(12) Patent Application Publication
(10) Pub. No.: US 2010/0235120 A1
(43) Pub. Date: Sep. 16, 2010

(54) ENERGY MANAGEMENT SYSTEM

(75) Inventor: Norbert Peter Vroege, Oegstgeest (NL)

Correspondence Address: YOUNG & THOMPSON, 209 Madison Street, Suite 500, Alexandria, VA, 22314, US

(73) Assignee: PLUGWISE B.V., Sassenheim (NL)

(21) Appl. No.: 12/523,603

(22) PCT Filed: Jan. 18, 2008
(86) PCT No.: PCT/NL2008/050033

§ 371 Date: May 24, 2010

(30) Foreign Application Priority Data
Jan. 18, 2007 (NL) 2000444

(51) Int. Cl. G01R 21/00; G06F 19/00

(52) U.S. Cl. 702/62

(57) ABSTRACT

Device and system for measuring the power consumption of individual power consumers in an office and the like. A simple device provides coupling to the respective consumer and sends the signal originating therefrom, with the aid of preferably ZigBee technology, to a central receiver, where it is processed. If appropriate, feedback is provided to the respective consumer. The central processing unit can not only be configured to provide information about the respective consumption to the consumer of the system but can also be programmed to display a comparison with the desired consumption. If appropriate, separate consumers can each be displayed. A circuit can be provided wherein the passage of power to one of the users is disconnected if a specific power consumption or the like is exceeded. It is also possible, for example for an energy company, to disconnect and connect a consumer which is coupled to the device remotely.

The present invention relates to a device according to the preamble of claim 1.

A device of this type is known from DE-100 64 165 which describes a system which is used in a household and in which an energy meter is attached in proximity to each power consumer. The location where the energy meter is positioned is not specified in DE-100 64 165.

GB-2 416 852 discloses a device which is to be connected between a user and an outlet and displays the consumption of the respective device on site. In some manner, the costs per unit associated with the consumption can be input and the total cost price can be calculated in combination with the consumption. In addition, the device can be set to switch off once a specific cost ceiling has been exceeded.

The desire to save energy has given rise to an increasing need to know the actual power consumption of specific consumers. In other words, the overall energy use is no longer the only factor taken into consideration; instead, it is examined how this use builds up. It has been found that this allows a considerable reduction in the energy use of specific consumers because the user realizes that such use is ineffective for a large proportion of the time. Examples include lights, power supplies for all types of appliances and the like.

The currently known devices for measuring individual consumption are not easy to install. They require particular tasks to be performed by a trained fitter, with all of the associated costs.

The object of the present invention is to lower the threshold for the use of devices of this type allowing energy consumption to be measured.

This object is achieved by the characteristics of claim 1.

According to the present invention, the device for measuring energy consumption, the sending thereof to a central point, such as a central processing unit or the like, is no longer incorporated in the outlet or further electrical infrastructure provided in a building, as in DE-100 64 165 A1, but is rather transferred to the electric feeder cable or the connection thereof for the respective user. As a result, the user is no longer dependent on the pre-existing electrical infrastructure in a building and each consumer of the respective device can be provided in a particularly simple manner. The presence of a receiver which influences the supply of power to the power user allows a power user of this type to be connected or disconnected remotely, using the central processing unit. This connection can be carried out for any conceivable reason. Examples of reasons for disconnection include payment problems or local overloading of the network during a connection. In other words, if, for example, both a washing machine and a dryer are provided with a device of this type and, for example, are connected to a group, one of the two can be disconnected.

In the event of a peak load resulting from considerable loading by a large number of connections, a completely different control can be used, the central processing unit deciding remotely that the energy consumption of the respective connection as a whole should be reduced. In this case, the respective central processing unit will be activated remotely in order (temporarily) to disconnect specific items of equipment. In addition, this allows energy companies to supply at various rates and to link this various-rate supply to the disconnection of specific consumers.

The transmitter which operates over a short distance can operate using any protocol known in the art, such as Bluetooth.

However, use is preferably made of a transmitter which operates with ZigBee.

In principle, there are a number of possibilities for attaching devices of this type.

Firstly, it is possible for the device to be integrated in the consumer, i.e. a lamp, computer, audiovisual appliance or a device of this type.

More important, however, are the other two possibilities, namely attachment in a supply cable, i.e. between the respective item of equipment and the plug thereof. A further possibility is the use of a wall-mounted module or intermediate piece which is placed between the plug of the respective item of equipment and the outlet. These last two possibilities can easily be retrofitted.

In an embodiment incorporating a wall-mounted module, this wall-mounted module preferably consists of a socket which is, in turn, provided with a plug. Preferably, both elements are attached in a compact housing. Components such as the receiver, transmitter, relay, sensor and the like are attached in the respective housing. In the embodiment in which the cable connecting the plug to the respective item of equipment is acted on directly, this item of equipment is preferably configured so as to be able to be attached by any user without risk. Preferably, the item of equipment is configured in such a way that, once the device according to the present invention has been attached to the cable, one of the cables is cut off, as a result of the performance of an internal cutting or clipping operation, and is connected in the circuit located in the device. This embodiment can also be provided with a receiver, transmitter, relay, sensor, etc. Obviously, the power consumption can also be measured with sensors, without cutting off the respective cable. However, cutting-off of the cable allows switching operations to be carried out.

In addition, the invention relates to a system comprising a number of devices for detecting the energy consumption of a number of energy consumers, wherein each device comprises a sensor for detecting the energy consumption of the energy consumer, a processor for processing the signal originating from said sensor and a transmitter which operates over a short distance for sending that signal to a central processing unit, and also to a processing device which is central to said devices and has a receiver and processor, wherein the central processing unit incorporates comparison means for comparing said receiver data with other data, at least one of the devices comprising a receiver which is combined with said transmitter, the receiver being configured for receiving a signal from that central point and which receiver switches a switch which is present in the device for the passage of power to said energy consumer and which central processing unit is provided with a transmitter which operates the receiver.

The use of comparison means allows the user easily to see how his use relates to a specific reference value. The specific reference value can be separately determined for consumers. The user can take measures on the basis of the specific reference value. However, it is also possible for measures to be taken automatically if specific values are exceeded. It is thus, for example, possible to connect or disconnect specific consumers.

The central processing unit can comprise a conventional personal computer. However, it is also possible to use a separate minicomputer which may or may not be provided with a display and preferably acts as a buffer and/or processing unit. The minicomputer can (temporarily) be linked to a computer operating in the conventional manner. As a result of the use of a central processing unit which is not a personal computer, a much smaller embodiment, which also consumes much less power, may be sufficient. A separate central processing unit of this type in that case does not have to be provided with a display. The devices which are connected between the network and the consumer and communicate with the central processing unit can also be provided with a display, although a display of this type is preferably omitted from the devices. After all, the user can easily detect the status from the central processing unit which may or may not be combined with a (personal) computer.

This system allows further management not only of electricity usage but also of the use of other utilities such as gas, water, telephone. Internet and cable television.

In addition, it is possible to forward the usage to the energy supplier. In the Netherlands, it should thus be possible to replace monthly bills paid in advance with a monthly bill for energy actually used. In this way, the consumer can immediately see what the consequences are of the use of specific appliances.

If use is made of a large number of devices which, in addition, are set apart from one another by a considerable distance, a transmitter which operates over a short distance is no longer sufficient. In such a case, there may be provided support stations which intercept the signal from a specific group of devices and forward it to the central processing device. In addition, a network configuration of this type can be configured in such a way that if one of the intermediate stations for any reason fails, another intermediate station can take over its activity.

The invention will be described hereinafter in greater detail with reference to exemplary embodiments illustrated in the drawings, in which:

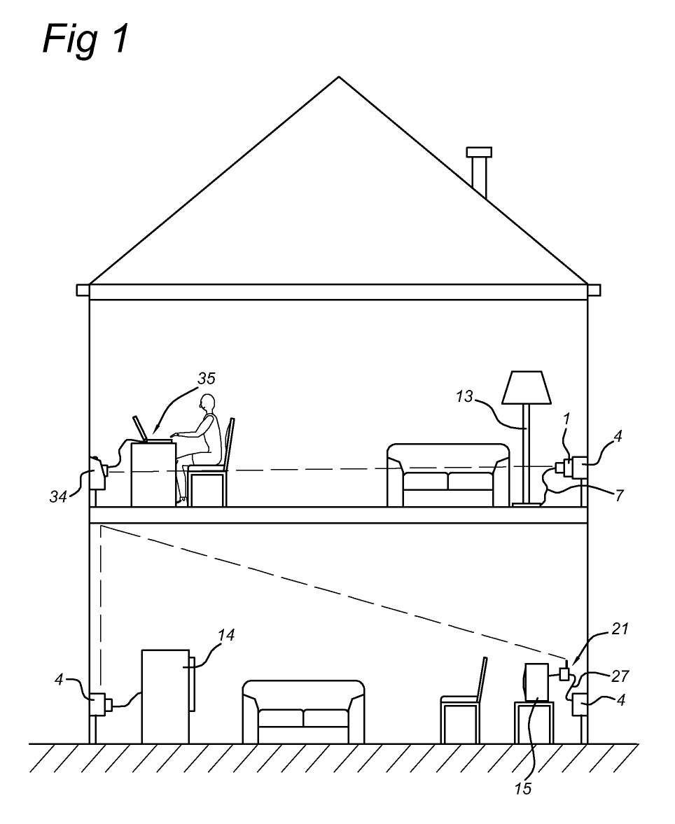

FIG. 1 is a schematic view of a house provided with the system according to the invention;

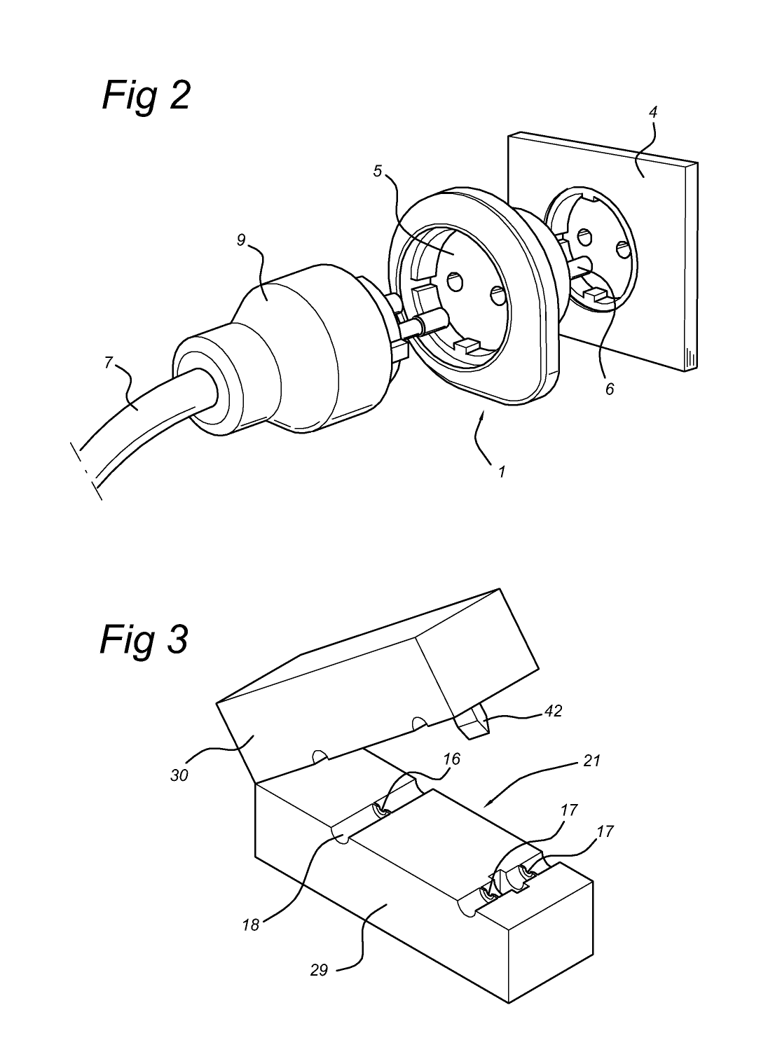

FIG. 2 shows a wall-mounted module according to the present invention;

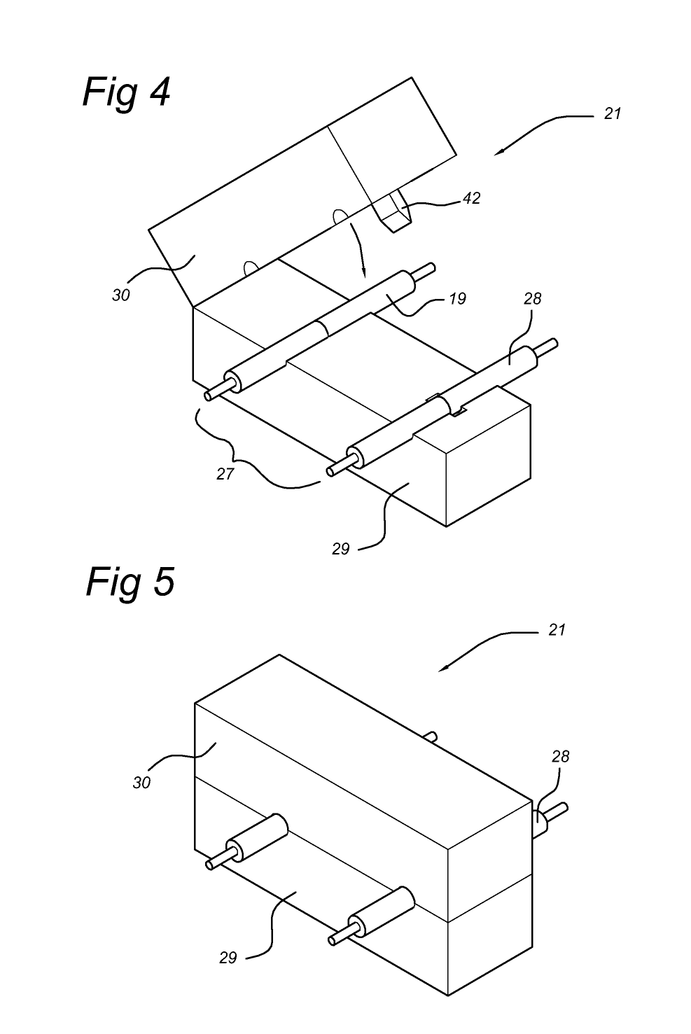

FIG. 3-6 show a module according to the invention which is to be incorporated in a cable;

FIG. 7 illustrates schematically the functioning of the module shown in the figures;

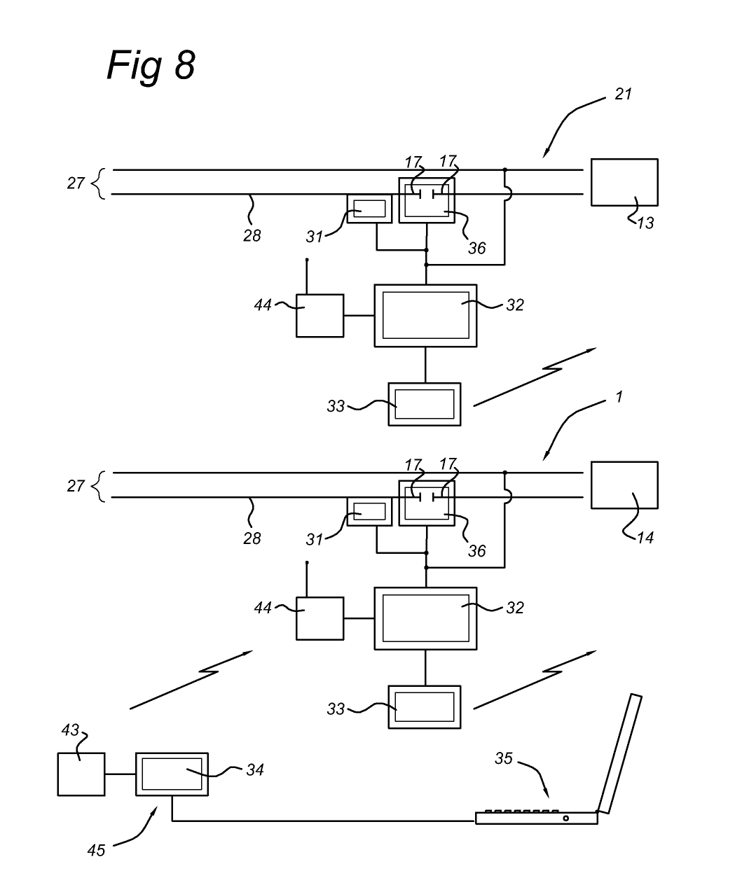

FIG. 8 shows a variation of the system shown in FIG. 7; and

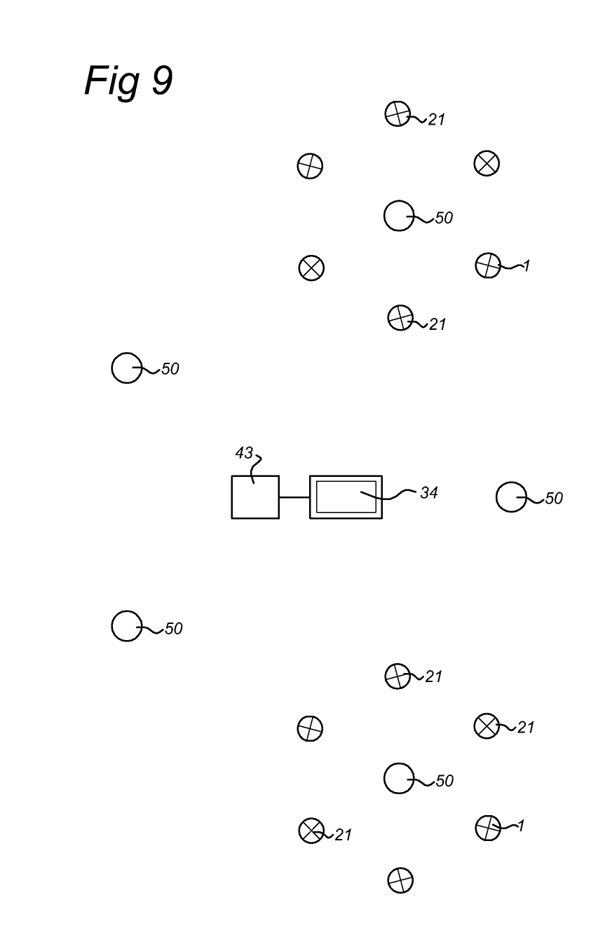

FIG. 9 shows a network comprising the system described hereinbefore.

FIG. 1 illustrates a house containing various users. These users are a lamp 13 with a cable 7, a refrigerator 14 and a television 15 with a cable 27. All of the users are connected to an outlet 4 via a cable.

A device 1 or 21 according to the present invention is connected in all cases between the outlet 4 and the respective consumer. Indicated schematically is the sending of these signals which are received by the receiver 34 and can be processed with a central processing unit. It is in this case possible for the receiver 34 to be configured with a minicomputer, i.e. to be capable of receiving and storing data. In addition, the minicomputer can preferably perform simple operations and may be provided with a (small) display. A receiver of this type consumes particularly little energy compared to a PC. By linking temporarily to the PC 35, the user can easily read and influence the respective values as will be described hereinafter. The receiver/central processing unit 34 can be configured as a stick to be inserted into the PC 35. As a result, the user is aware at all times of the consumption of each of the consumers 13-15. More particularly, he is aware of the individual consumption of each of the consumers and can take measures if appropriate.

FIG. 2 shows an example of the device 1. The outlet is denoted by reference numeral 4 and the plug 9 is fastened to the cable 7 of a respective consumer. According to the present invention, a wall-mounted module 1 can be used. The wall-mounted module consists of a socket part 5 and a plug part 6. This allows the user to connect the wall-mounted module between the outlet 4 and the plug 9. The wall-mounted module contains the electronics as will be described with reference to FIG. 7-9.

FIG. 3-6 illustrate another example of the invention. The cable of the consumer is in this case denoted by reference numeral 27, consists of conductors 19 and 28, and this consumer is provided in the conventional manner with a plug or other connection to the electrical infrastructure of the house.

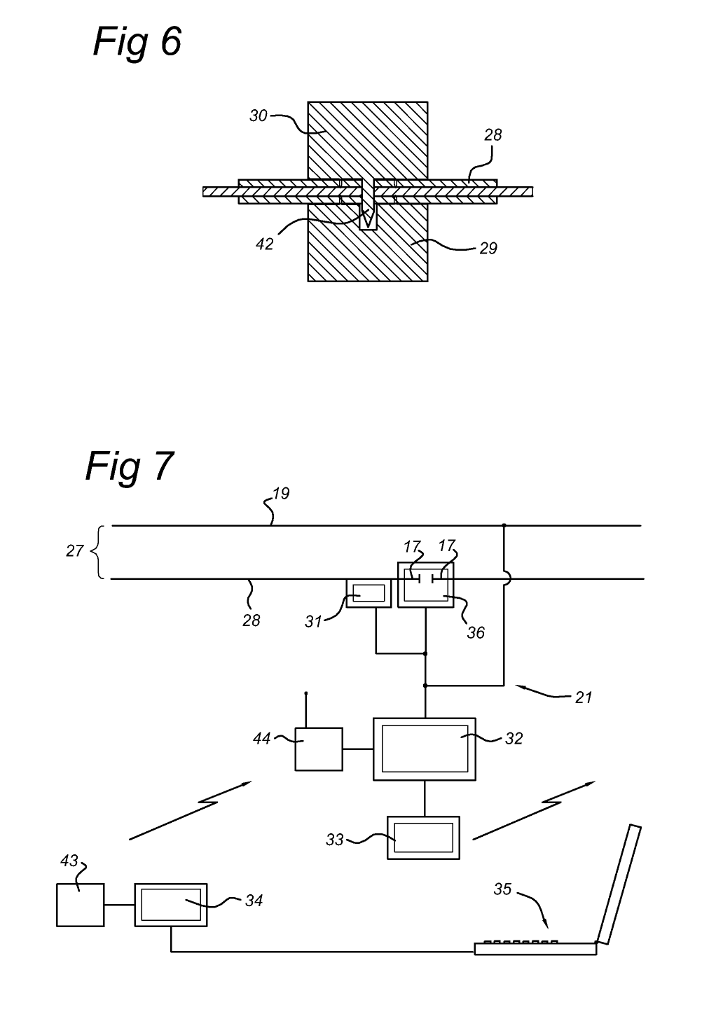

According to the present invention, use is made of a device 21 which can easily be positioned around the cable 27. This encloses the separate conductors. The device 21 consists of two parts 29, 30 which are attached so as to be able to hinge with respect to each other. The parts are each provided with receptacles 18 for receiving the conductors. In this case, a clipping unit 42 is provided on one side. When the parts 29 and 30 are joined together, the insulated clipping unit 42 will divide the (electrical) conductor 28 in two, as is shown in FIG. 6. Each of the cable parts is in contact with the electronics to be described hereinafter via the respective contact points 17. The other conductor 19 consumes power via the contact 16. The contact points 17 can be connected via a relay 36.

FIG. 7 shows the example of the cable 27, merely the conductor 28 being cut off at the contact points 17. The contact points lead to the relay 36 and the sensor 31 connected thereto. The sensor 31 is used to measure the amount of energy passing through the cable 28 (when the relay 36 is closed) and this amount is processed in the processor 32 which is also received in the part 29 or 30. On this basis, the transmitter 33 is used to send a signal, in one of the parts 29 or 30, to the receiver 34 in accordance with the ZigBee protocol or another protocol. After processing, the signal is subsequently sent to a processor 35 such as a laptop. In the present example, the receiver 34 is integrated in a minicomputer, although it can also be connected to a separate computer. A minicomputer of this type uses particularly little energy and can act as a storage memory in order to supply the respective data to the laptop when the laptop is connected. In addition, a minicomputer of this type allows the energy supplier to be provided with data concerning the energy consumption. This minicomputer can operate independently of a laptop. On the laptop, the user can see what the usage is of the consumer 15 connected to the cable 27. In this case, the laptop 35 can contain a table showing the optimum usage of the consumer 15. In addition, when a specific value is exceeded, a signal can actively be sent from the laptop 35 using the transmitter 43, as a result of which the relay 36 is excited via the receiver 44, present in one of the parts 29 or 30, and the respective consumer 15 is disconnected.

The use of, in particular, ZigBee technology allows energy consumption to be kept particularly low. It is thus possible to attach in the devices 1, 21 a power supply which is independent of the energy network, the used battery in the respective housing for the above-described transmitter having a comparatively long service life.

It is possible non-continuously to provide a connection between the device 1, 21 and the central processing unit 34, 35. This can be carried out periodically, thus allowing the energy consumption to be further restricted and allowing the service life of the device 1, 21 to be lengthened further without having to exchange batteries and the like. ZigBee technology allows comparatively large distances to be bridged, so any house, office or the like can easily be provided with the above-described embodiment. Obviously, the various components are provided with software which may or may not be embedded software.

FIG. 8 shows a system which corresponds substantially to that illustrated in FIG. 7. The corresponding parts are provided with the same reference numerals.

However, in contrast to the embodiment shown in FIG. 7, the receiver/central processing unit 34 is provided with an input 45. This input may, for example, be an Internet connection or a (wireless) GPRS modem. The central processing unit 34 is thus influenced remotely. The embodiment of FIG. 8 shows two users 13 and 14, one provided with a device 1 and one provided with a device 21 according to the invention. Both are also provided with a receiver 44 which is integrated therein and with which it is possible to connect and disconnect one or both relays 36 via the transmitter 43.

The external connection 45 now allows one (or both) of the two users 13 or 14 to be disconnected remotely, for example by an energy company. This is possible in the case of, for example, unpaid bills, the threat of overloading in energy supply in the building or the threat of overloading on a relatively large scale, i.e. in a large group of connections. It is thus possible, for example, automatically to eliminate peak loads. This can be used, for example, in the case of devices 13, 14 which do not have to operate immediately, such as refrigerators and washing machines. Connection thereof can usually be delayed without difficulty by half an hour or more, allowing the peak load on the network to fall considerably.

FIG. 9 shows schematically the carrying-out of the invention in a relatively large space. The receiver/central processing unit is denoted by reference numeral 34 and can be connected to a laptop in the manner described hereinbefore. A receiver/central processing unit of this type can, for example, be configured as a stick in order easily to be inserted into a PC, although other embodiments are also possible. A large number of devices 1, 21 are shown. Because this space is comparatively large, it is not possible to allow all of the devices to communicate directly with the receiver 34. Intermediate stations 50 are therefore provided. Each of the devices 1, 21 communicates with the respective intermediate station 50 and the respective intermediate station 50 communicates with the receiver 34. Under certain circumstances, it is possible that an intermediate station 50 may not be able to communicate with the receiver 34 or, conversely, that the transmitter 43 which is provided for receiving may not be able to communicate with the respective intermediate station 50. In that case, communication can be carried out via another intermediate station 50. It is also possible for a respective user 1/21 to communicate with the receiver 34 via another intermediate station 50. The devices 1, 21 can communicate with one another, for example in a MESH network.

The present invention allows users 13-15 to be connected and disconnected. This can be carried out using information present in the devices 1, 21 themselves, such as an internal clock. It is also possible to connect and disconnect remotely (if appropriate using a central clock). It is also possible to generate summaries of the usage of separate users 13-15 or a plurality of users. Comparisons are possible, as are summaries over time.

On reading the foregoing description, a person skilled in the art will immediately think of variations which fall within the scope of the appended claims.

1-14. (canceled)

15. A device comprising a sensor for detecting the energy consumption of an energy consumer, a processor for processing the signal originating from said sensor and a transmitter which operates over a short distance for sending that signal to a central processing unit, said device comprising means for direct coupling to the electric feeder cable of said user, said device comprising a receiver which is combined with said transmitter, said receiver being configured for receiving a signal from said central processing unit, said receiver switching a switch which is present in said device for the passage of power to said energy consumer.

16. The device as claimed in claim 15, comprising a transmitter which operates with ZigBee.

17. A system comprising a number of devices for detecting the energy consumption of a number of energy consumers, wherein each device comprises a sensor for detecting the energy consumption of said energy consumer, a processor for processing the signal originating from said sensor and a transmitter which operates over a short distance for sending that signal to a central processing unit which is shared, for said devices, with a receiver and processor, said central processing unit incorporating comparison means for comparing said receiver data with other data, at least one of the devices comprising a receiver which is combined with said transmitter, which receiver is configured for receiving a signal from said central processing unit and which receiver switches a switch which is present in said device for the passage of power to said energy consumer and which central processing unit is provided with a transmitter which operates said receiver.

18. The system as claimed in claim 17, wherein said other data includes a previously input value.

19. The system as claimed in claim 17, wherein said central processing unit is configured for the connecting of a device as a result of that comparison.

20. The system as claimed in claim 17, wherein said central processing unit comprises a 30 minicomputer provided with an output for communication with a computer.

21. The system as claimed in claim 17, wherein said central processing unit is provided with an input which can be operated remotely for the controlling of said transmitter.

22. The system as claimed in claim 21, wherein said input comprises an Internet connection.

23. The system as claimed in either claim 21, wherein said input comprises a wireless connection.

24. The system as claimed in claim 17, comprising various devices, each provided with a transmitter-controlled switch, wherein said central processing unit is adjustable for separately determining the switching of the switch in question.
